(19) United States
(12) Patent Application Publication
(10) Pub. No.: US 2008/0045040 A1
(43) Pub. Date: Feb. 21, 2008

(54) Laser Spike Anneal With Plural Light Sources

(75) Inventor: Takashi Nakao, Naka-gun (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/465,178

(22) Filed: Aug. 17, 2006

(51) Int. Cl. H01L 21/00

(52) U.S. Cl. 438/795

(57) ABSTRACT

A semiconductor wafer is preheated in advance of laser annealing by directing focused energy from a first energy source onto a local area of the wafer. High power laser light from a second energy source is then directed onto the preheated local area to further increase the temperature for annealing. The first energy source can emit laser light, white light, electron beams, gamma radiation, or other type of focused energy to preheat a local area of the wafer in advance of applying the high power laser light for annealing.

### BACKGROUND OF THE INVENTION

During laser spike annealing (LSA) in the manufacture of semiconductor wafers, thermal energy for annealing is provided by applying laser light to the surface of the wafer for very short time intervals, typically from several nanoseconds to several milliseconds. Heat energy from the laser light raises the temperature of the wafer surface to very high temperatures for annealing, typically in excess of 1000° C.

One laser annealing system available from Applied Materials, Inc. (Santa Clara, Calif.) delivers laser light having a wavelength from 500 to 800 nm. While such systems are useful for some applications, laser light of this wavelength is prone to interference due to variations in pattern density along the wafer. This interference can lead to variations in absorption and, as a result, non-uniform annealing of the wafer. It has been proposed to use two lasers emitting light of different wavelengths, such as 500 nm and 800 nm, to help compensate for variations in pattern density.

Another laser spike annealing system, available from Ultratech (San Jose, Calif.), emits very long wavelength laser light, e.g., wavelength >10 μm. The relatively longer wavelength laser light helps to reduce pattern density effects of absorption, resulting in more uniform annealing. One of the drawbacks associated with this type of system is lower energy output, which makes the light less effective in free carrier (electron) generation and less efficient in transferring heat. To help compensate for the lower energy output, the wafer typically is preheated in an oven to 400° C. to create free electrons at the surface of the wafer, as illustrated in FIGS. 1A-1B. Free electrons at the surface enable the laser light to be absorbed more efficiently so that higher temperatures can be achieved for annealing.

When annealing with long wavelength laser light as described above, the wafer typically is maintained in an oven at 400° C. for a period of 200 to 600 seconds. As the laser scans the surface of the wafer (e.g., from left to right on the wafer illustrated in FIG. 2), the local surface temperature is increased to about 1300° C. for about 1-20 milliseconds, after which time the temperature returns to the ambient 400° C. until the annealing process is completed. As a result, a given area of the wafer is kept at 400° C from a time beginning shortly after the laser scans the area until a time at which the remaining areas of the wafer are annealed. Areas of the wafer which are annealed toward the beginning of the scan thus are held at 400° C. for a longer period of time post-annealing than are those areas which are annealed toward the end of the scan.

Post-annealing temperatures of 400° C. contribute to such problems as arsenic deactivation, metallic contamination, and scratching or other defects resulting from thermal expansion. Holding the wafer at these temperatures for longer periods of time can increase the frequency and/or extent of these problems. The wafer shown in FIG. 2 illustrates that the first-annealed (left-hand) portions of the wafer experience the most significant contamination and arsenic deactivation, while the later-annealed (right-hand) portions of the wafer experience less significant levels of contamination and deactivation. Arsenic deactivation itself is undesirable, particularly when the levels of deactivation are non-uniform across the wafer surface as shown in FIG. 2.

There remains a need for improved techniques for laser spike annealing of semiconductor wafers. It would be particularly desirable to develop a technique that reduces the propensity of contamination, arsenic deactivation, and defects resulting from thermal expansion, and which has the potential to result in more uniform annealing.

### SUMMARY OF THE INVENTION

One aspect of the present invention is directed to a method and apparatus for laser annealing a semiconductor wafer. Focused energy is directed from a first energy source onto a wafer to heat a local area of the wafer to a temperature of about 250 to about 750° C. Laser light from a second energy source is then directed onto the local area to heat the local area to a temperature of at least about 1000° C. for annealing. In one preferred embodiment, a first energy source is a laser adapted to emit laser light having a wavelength from about 40 to about 800 nm. The second laser source preferably is adapted to emit laser light having a wavelength of at least about 10 μm. Alternatively, the first energy source can be adapted to emit white light, electron beams, gamma radiation, or other type of focused energy.

By using a focused energy source for preheating a local area of the wafer, it is possible to generate free electrons to improve laser absorption without the need to keep the entire wafer at elevated temperatures as the laser spike annealing is completed in remaining areas of the wafer. The present invention has the potential to overcome many of the above-described drawbacks associated with present laser spike annealing techniques. The present invention is useful in a variety of applications, including large scale integration (LSI) devices, NAND flash memory, and the like.

### BRIEF DESCRIPTIONS OF THE DRAWINGS

The present invention will now be described in more detail with reference to embodiments of the invention, given only by way of example, and illustrated in the accompanying drawings in which:

FIGS. 1A and 1B illustrate preheating a wafer in an oven to 400° C. to create free electrons at the surface of the wafer. Free electrons at the surface enable long wavelength laser light to be absorbed more efficiently.

FIG. 2 illustrates arsenic deactivation resulting from holding the wafer at 400° C. as annealing is completed. The first-annealed (left-hand) areas of the wafer experience the most significant contamination and arsenic deactivation because these areas are held at 400° C. post-annealing for the longest time.

FIG. 3 illustrates applying 500-800 nm laser light for photoexcitation, followed by high power 10 μm laser light for annealing in accordance with a preferred embodiment of the present invention.

FIG. 4 schematically illustrates free electron generation resulting from application of 500-800 nm laser light in the embodiment of FIG. 3.

FIG. 5 illustrates applying 1000 nm white light for free carrier generation, followed by high power 10 μm laser light for annealing in accordance with an alternative embodiment of the present invention.

FIG. 6 schematically illustrates free electron generation resulting from application of 1000 nm white light in the embodiment of FIG. 5.

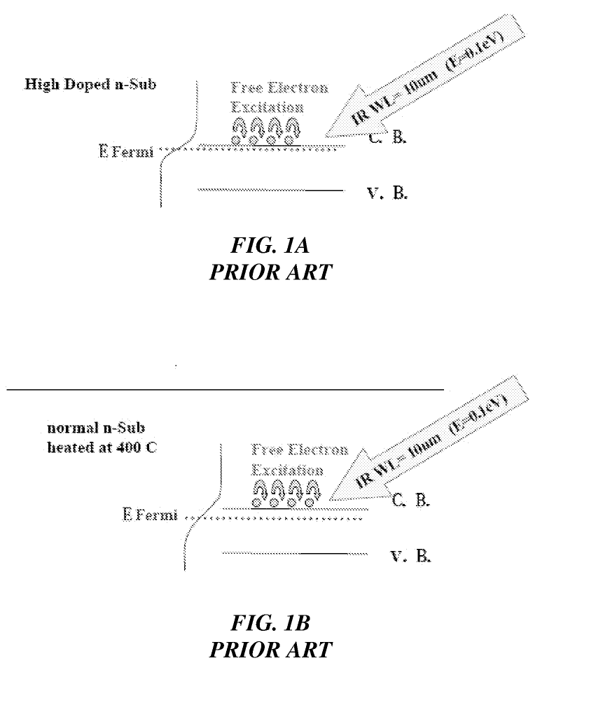

### DETAILED DESCRIPTION OF THE INVENTION

In the practice of the present invention, a semiconductor wafer is preheated in advance of laser spike annealing by first directing focused energy from a first energy source onto a local area of the wafer. The first energy source generates free electrons to improve absorption by high power laser light from a second energy source, which increases the temperature of the local area for annealing.

The terms “focused,” “local area,” and similar terms are used herein in connection with selectively applying energy to a restricted portion of a wafer surface. In the embodiments described below, focused energy is applied using laser light or white light. It should be recognized that these energy sources are exemplary and not limiting. Various other energy sources can be used, non-limiting examples of which include electron beams, gamma radiation, and the like. In general, an energy source is considered “focused” when it is capable of heating a portion of the wafer without heating the wafer as a whole, as does an oven.

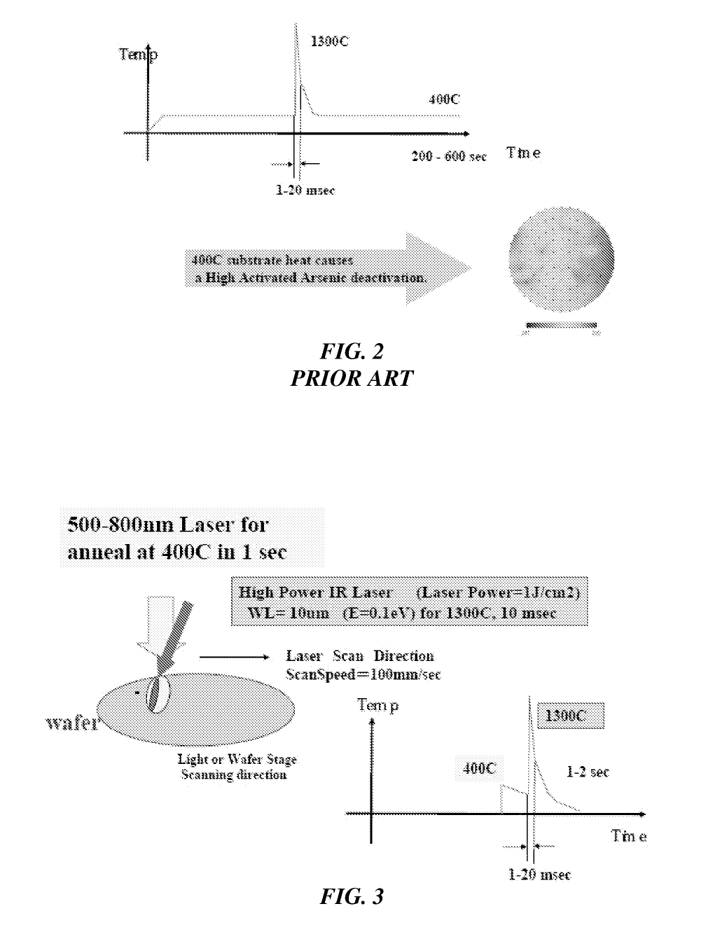

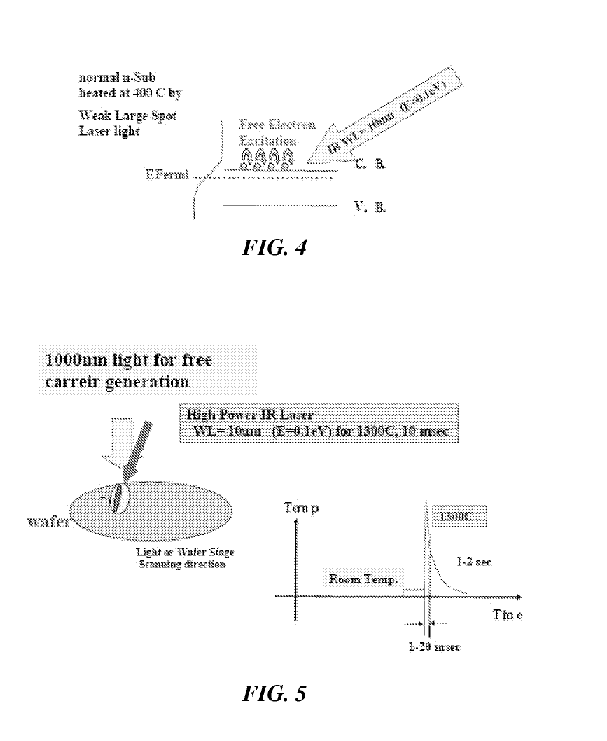

The first energy source can emit laser light, white light, electron beams, gamma radiation, or other type of energy sufficient to preheat a local area of the wafer in advance of applying high power laser light for annealing. In one preferred embodiment illustrated in FIG. 3, the first energy source is a laser. The wavelength of the laser light preferably is selected so that a local area of the wafer can be heated to a temperature of about 250 to about 750° C., preferably about 400 to about 500° C., in a relatively short time, preferably in less than 3 seconds and often in about 1 second or less, depending on such factors as the materials used in the wafer. Most often, the wavelength of the laser light is less than 1 μm and typically ranges from about 40 to about 800 nm. In one embodiment, laser light having a wavelength of from about 500 to about 800 nm is used. The power of the laser for the first energy source varies depending on wavelength, typically ranging from about 0.2 to about 2 J/cm². Such lasers are effective for generating free electrons near the surface of the wafer by photoexcitation, as illustrated in FIG. 4.

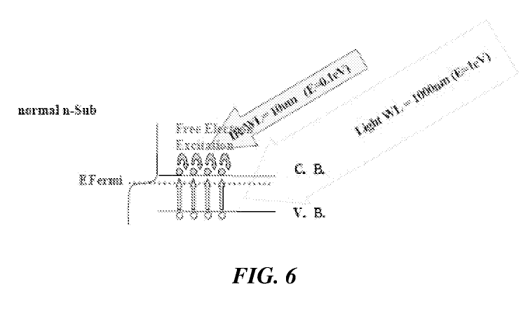

FIG. 5 illustrates an alternative embodiment in which the first energy source emits white light having a wavelength of 1000 μm (E=1 eV). Light of this wavelength is also useful in heating a local area of the wafer to the above-described temperatures in a relatively short time, typically on the order of 1-2 seconds. FIG. 6 illustrates the efficacy of the white light in free carrier generation.

The particular temperature to which the first energy source raises the local area of the wafer is not critical as long as free carrier electrons are generated. After the local area is preheated by the first energy source, the high power laser is able to achieve uniform annealing. For many common materials, temperatures of about 400 to 500° C. are preferable for generating free electrons to improve absorption of the laser light emitted by the second energy source.

The second energy source can be, for example, a high powered CO₂ laser. An example of a commercially available product is LSA100®, available from Ultratech (San Jose, Calif.). This device emits laser light having a wavelength of >10 μm (E=0.1 eV). The power of the laser for the second energy source varies depending on wavelength, typically ranging from about 0.1 to about 1 J/cm².

Several different techniques can be used for scanning the surface of the wafer with laser light. For example, the source of laser light can be maintained relatively stationary while the wafer is oscillated so that the laser anneals the desired surfaces of the wafer. Alternatively, the wafer can be maintained relatively stationary while the source of laser light oscillates to scan the wafer surface. Yet another alternative is to oscillate both the wafer and the source of laser light relative to each other, which potentially can yield faster scanning speeds.

Annealing temperature and annealing time can be adjusted by adjusting such parameters as laser power and scan speed, as will be apparent to persons skilled in the art. Using a laser power of 1 J/cm² and laser spot width of 200 μm, laser light can scan a silicon wafer surface at a speed of about 100 mm/sec. The laser light typically increases the temperature of the wafer surface to at least 1000° C., often about 1200 to about 1300° C., for an interval of several milliseconds.

Other embodiments of the present invention will be apparent to those skilled in the art from consideration of the specification and practice of the invention. It is intended that the specification and the disclosed embodiments be considered exemplary only, with a true scope and spirit of the invention being indicated by the appended claims.

What is claimed is:

1. A method of laser annealing a semiconductor wafer, the method comprising:
directing focused energy from a first energy source onto a wafer to heat a local area of the wafer to a temperature of about 250 to about 750° C.; and
directing laser light from a second energy source onto the local area to heat the local area to a temperature of at least about 1000° C. for annealing.

2. The method of claim 1 wherein the first energy source emits laser light.

3. The method of claim 2 wherein the laser light from the first energy source has a wavelength from about 40 to about 800 nm.

4. The method of claim 3 wherein the laser light from the first energy source has a wavelength from about 40 to about 100 nm.

5. The method of claim 3 wherein the laser light from the first energy source has a wavelength from about 500 to about 800 nm.

6. The method of claim 1 wherein the first energy source emits white light having a wavelength of about 100 to about 1000 nm.

7. The method of claim 1 wherein the second energy source emits laser light having a wavelength of at least about 10 μm.

8. The method of claim 1, wherein the wafer is kept relatively stationary and the first and second energy sources are moved relative to the wafer.

9. The method of claim 1, wherein the first and second energy sources are kept relatively stationary and the wafer is moved relative to the energy sources.

10. The method of claim 1, wherein both the wafer and energy sources are moved relative to each other.

11. An apparatus for laser annealing a semiconductor wafer, the apparatus comprising:
a first energy source adapted to emit focused energy onto a wafer to heat a local area of the wafer to a temperature of about 250 to about 750° C.; and
a second energy source adapted to emit laser light onto the local area to heat the local area to a temperature of at least about 1000° C. for annealing.

12. The apparatus of claim 11 wherein the first energy source is adapted to emit laser light.

13. The apparatus of claim 12 wherein the laser light from the first energy source has a wavelength from about 40 to about 800 nm.

14. The apparatus of claim 13 wherein the laser light from the first energy source has a wavelength from about 40 to about 100 nm.

15. The apparatus of claim 13 wherein the laser light from the first energy source has a wavelength from about 500 to about 800 nm.

16. The apparatus of claim 11 wherein the first energy source is adapted to emit white light having a wavelength of about 100 to about 1000 nm.

17. The apparatus of claim 11 wherein the second energy source is adapted to emit laser light having a wavelength of at least about 10 μm.

18. An apparatus for laser annealing a semiconductor wafer, the apparatus comprising:
a first laser source adapted to emit laser light having a wavelength from about 40 to about 800 nm to heat the wafer to a first temperature; and
a second laser source adapted to emit laser light having a wavelength of at least about 10 μm to heat the wafer to a second temperature, wherein the second temperature is greater than the first temperature.

19. The apparatus of claim 18 wherein the first laser source is adapted to emit laser light having a wavelength from about 40 to about 100 nm.

20. The apparatus of claim 18 wherein the first laser source is adapted to emit laser light having a wavelength from about 500 to about 800 nm.
